(19) United States
(12) Patent Application Publication
(10) Pub. No.: US 2011/0294235 A1
(43) Pub. Date: Dec. 1, 2011

(54) METHOD OF FORMING A SEMICONDUCTOR DEVICE

(75) Inventor: Takuro MAEDE, Tokyo (JP)

(73) Assignee: ELPIDA MEMORY INC., Tokyo (JP)

(21) Appl. No.: 13/112,651

(22) Filed: May 20, 2011

(30) Foreign Application Priority Data
May 31, 2010 (JP) 2010-124645

(51) Int. Cl. H01L 21/66

(52) U.S. Cl. 438/14; 257/E21.53

(57) ABSTRACT

A method of forming a semiconductor device includes the following processes. A groove is formed in a semiconductor substrate. A first film is formed in a device-formation region and a non-device-formation region of a semiconductor substrate. The first film is patterned to form a second film in the device-formation region and a monitoring pattern in the non-device-formation region. First and second structures are formed over the second film and the monitoring pattern respectively. The first structure has substantially the same pattern defined in a horizontal direction as the second structure. The first and second structures are polished.

### BACKGROUND OF THE INVENTION

1. Field of the Invention

The present invention generally relates to a method of forming a semiconductor device.

Priority is claimed on Japanese Patent Application No. 2010-124645, May 31, 2010, the content of which is incorporated herein by reference.

2. Description of the Related Art

Semiconductor devices being capable of memory operations include a memory cell which includes a combination of a selection element and a memory element. In typical cases, a MOS transistor (Metal Oxide Semiconductor transistor) may be used as the selection element.

When the semiconductor device is a DRAM (Dynamic Random Access Memory), a capacitor is used as the memory element. When the semiconductor device is a PRAM (Phase Change RAM), a phase change material is used as a material for forming the memory element.

FIGS. 12 and 13 show fragmentary plan views illustrating memory cells including a MOS transistor in accordance with the related art. FIGS. 12 and 13 illustrate in plan view memory cell elements of the memory cells, wherein the memory cell elements of each memory cell are disposed in different levels. In FIGS. 12 and 13, a Y-direction indicates an extending direction of a gate electrode 204. An X-direction is perpendicular to the Y-direction. In FIG. 13, the same components as those shown in FIG. 12 are indicated by the same reference numerals.

The memory cell illustrated in FIG. 12 includes an isolation region 202 and a plurality of active regions 203 on the semiconductor substrate 201. The plurality of active regions 203 is arrayed and defined by the isolation region 202. The gate electrode 204 is disposed in the memory cell. The gate electrode 204 extends in the Y-direction. The gate electrode 204 crosses the active region 203. The gate electrode 204 is a component of the MOS transistor. A part of a word line functions as the gate electrode 204.

The gate electrode 204 has side surfaces 204a. Side walls 206 are provided on the side surfaces 204a. The side walls 206 are an insulating film and may, for example, be a silicon nitride film. A bit line 207 is provided to cross the gate electrode 204 which is the part of the word line. The bit line 207 extends in the X-direction. The bit line 207 extends in not straight. In some cases, the bit line may extend in wavy form. The bit line 207 is connected to one of source and drain regions of the MOS transistor.

The memory cell illustrated in FIG. 13 includes a contact plug (not shown). The contact plug connects one of the source and drain regions of the MOS transistor and the bit line 207. The other contact plug connects the other of the source and drain regions of the MOS transistor and a memory element (not shown) which is provided over the bit line 207.

Japanese Unexamined Patent Application, First Publication, No. JP-A-2007-294618 discloses the following processes. A mask pattern having an opening is formed, using a photoresist film, on an insulating film (not shown) in which a contact hole 211 will be formed. A contact plug is connected to a source or drain region. The contact plug is formed by SAC (Self Alignment Contact) process.

### SUMMARY

In one embodiment, a method of forming a semiconductor device may include, but is not limited to, the following processes. A first film is formed in a device-formation region and a non-device-formation region of a semiconductor substrate. The first film is patterned to form a second film in the device-formation region and a monitoring pattern in the non-device-formation region. First and second structures are formed over the second film and the monitoring pattern respectively. The first structure has substantially the same pattern defined in a horizontal direction as the second structure. The first and second structures are polished.

In another embodiment, a method of forming a semiconductor device may include, but is not limited to, the following processes. First and second structures in a device-formation region and a non-device-formation region respectively are polished concurrently. The first structure has substantially the same pattern defined in a horizontal direction as the second structure. The second structure is over a monitoring pattern. Polishing the first and second structures is terminated at the same time or after the monitoring pattern is shown. A top surface of the first structure is smaller in area than a top surface of the second structure.

In still another embodiment, a method of forming a semiconductor device may include, but is not limited to, the following processes. An impurity diffusion layer is formed in a first region of a semiconductor substrate. A first film is formed over the first region and a second region of the semiconductor substrate. The first film is patterned to form a second film and a monitoring pattern in the first and second regions respectively. A third film is formed over the first and second regions. First and second grooves and a contact hole are formed in the third film. The first groove is formed over the second film. The second groove is formed over the monitoring pattern. The impurity diffusion layer is shown through the contact hole. A conductive film is formed to fill the first and second grooves and the contact hole. The conductive film is polished to form a contact plug in the contact hole. The contact plug is in contact with the impurity diffusion layer.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary plan view illustrating a semiconductor substrate including a plurality of formation regions of a semiconductor device and an insulating film in accordance with one embodiment of the present invention;

FIG. 2 is a fragmentary plan view illustrating a memory cell provided in the semiconductor device in accordance with one embodiment of the present invention;

FIG. 3A is a fragmentary cross sectional elevation view, taken along an E-E line of FIG. 2, illustrating the semiconductor device in accordance with one embodiment of the present invention;

FIG. 3B is a fragmentary cross sectional elevation view, taken along an F-F line of FIG. 2, illustrating the semiconductor device in accordance with one embodiment of the present invention;

FIG. 3C is a fragmentary cross sectional elevation view, taken along a scribe line C, illustrating a structure including the formation region of the insulating film in accordance with one embodiment of the present invention;

FIG. 4A is a fragmentary cross sectional elevation view, taken along the E-E line of FIG. 2, illustrating the semiconductor device in a step involved in a method of forming the semiconductor device of FIG. 3A in accordance with one embodiment of the present invention;

FIG. 4B is a fragmentary cross sectional elevation view, taken along the F-F line of FIG. 2, illustrating the semiconductor device in a step involved in a method of forming the semiconductor device of FIG. 3B in accordance with one embodiment of the present invention;

FIG. 4C is a fragmentary cross sectional elevation view, taken along the G-G line of FIG. 2, illustrating the semiconductor device in a step involved in a method of forming the semiconductor device of FIG. 3C in accordance with one embodiment of the present invention;

FIG. 5A is a fragmentary cross sectional elevation view, taken along the E-E line of FIG. 2, illustrating the semiconductor device in a step, subsequent to the step of FIGS. 4A to 4C, involved in a method of forming the semiconductor device of FIG. 3A in accordance with one embodiment of the present invention;

FIG. 5B is a fragmentary cross sectional elevation view, taken along the F-F line of FIG. 2, illustrating the semiconductor device in a step, subsequent to the step of FIGS. 4A to 4C, involved in a method of forming the semiconductor device of FIG. 3B in accordance with one embodiment of the present invention;

FIG. 5C is a fragmentary cross sectional elevation view, taken along the G-G line of FIG. 2, illustrating the semiconductor device in a step, subsequent to the step of FIGS. 4A to 4C, involved in a method of forming the semiconductor device of FIG. 3C in accordance with one embodiment of the present invention;

FIG. 6 is a fragmentary plan view illustrating a shape and a position of a photoresist pattern formed in a structure illustrated in FIGS. 5A and 5B in accordance with one embodiment of the present invention;

FIG. 7A is a fragmentary cross sectional elevation view, taken along the E-E line of FIG. 2, illustrating the semiconductor device in a step, subsequent to the step of FIGS. 5A to 5C, involved in a method of forming the semiconductor device of FIG. 3A in accordance with one embodiment of the present invention;

FIG. 7B is a fragmentary cross sectional elevation view, taken along the F-F line of FIG. 2, illustrating the semiconductor device in a step, subsequent to the step of FIGS. 5A to 5C, involved in a method of forming the semiconductor device of FIG. 3B in accordance with one embodiment of the present invention;

FIG. 7C is a fragmentary cross sectional elevation view, taken along the G-G line of FIG. 2, illustrating the semiconductor device in a step, subsequent to the step of FIGS. 5A to 5C, involved in a method of forming the semiconductor device of FIG. 3C in accordance with one embodiment of the present invention;

FIG. 8A is a fragmentary cross sectional elevation view, taken along the E-E line of FIG. 2, illustrating the semiconductor device in a step, subsequent to the step of FIGS. 7A to 7C, involved in a method of forming the semiconductor device of FIG. 3A in accordance with one embodiment of the present invention;

FIG. 8B is a fragmentary cross sectional elevation view, taken along the F-F line of FIG. 2, illustrating the semiconductor device in a step, subsequent to the step of FIGS. 7A to 7C, involved in a method of forming the semiconductor device of FIG. 3B in accordance with one embodiment of the present invention;

FIG. 8C is a fragmentary cross sectional elevation view, taken along the G-G line of FIG. 2, illustrating the semiconductor device in a step, subsequent to the step of FIGS. 7A to 7C, involved in a method of forming the semiconductor device of FIG. 3C in accordance with one embodiment of the present invention;

FIG. 9A is a fragmentary cross sectional elevation view, taken along the E-E line of FIG. 2, illustrating the semiconductor device in a step, subsequent to the step of FIGS. 8A to 8C, involved in a method of forming the semiconductor device of FIG. 3A in accordance with one embodiment of the present invention;

FIG. 9B is a fragmentary cross sectional elevation view, taken along the F-F line of FIG. 2, illustrating the semiconductor device in a step, subsequent to the step of FIGS. 8A to 8C, involved in a method of forming the semiconductor device of FIG. 3B in accordance with one embodiment of the present invention;

FIG. 9C is a fragmentary cross sectional elevation view, taken along the G-G line of FIG. 2, illustrating the semiconductor device in a step, subsequent to the step of FIGS. 8A to 8C, involved in a method of forming the semiconductor device of FIG. 3C in accordance with one embodiment of the present invention;

FIG. 10A is a fragmentary cross sectional elevation view illustrating a semiconductor device involved in a step of a method of forming a semiconductor device according to a comparative example;

FIG. 10B is a fragmentary cross sectional elevation view illustrating a semiconductor device involved in a step of the method of forming the semiconductor device according to the comparative example;

FIG. 10C is a fragmentary cross sectional elevation view illustrating a semiconductor device involved in a step of the method of forming the semiconductor device according to the comparative example;

FIG. 11A is a fragmentary cross sectional elevation view illustrating a semiconductor device involved in a step of the method of forming the semiconductor device according to the comparative example;

FIG. 11B is a fragmentary cross sectional elevation view illustrating a semiconductor device involved in a step of the method of forming the semiconductor device according to the comparative example;

FIG. 11C is a fragmentary cross sectional elevation view illustrating a semiconductor device involved in a step of a method of forming a semiconductor device according to the comparative example;

FIG. 12 is a fragmentary plan view illustrating a memory cell including a MOS transistor in accordance with the related art;

FIG. 13 is a fragmentary plan view illustrating the memory cell including the MOS transistor in accordance with the related art; and

FIG. 14 is a fragmentary plan view illustrating a memory cell including a MOS transistor in accordance with the related art.

### DETAILED DESCRIPTION OF THE PREFERRED EMBODIMENTS

Before describing the present invention, the related art will be explained in detail, in order to facilitate the understanding of the present invention.

With the progress of miniaturization of the semiconductor devices in recent years, the size of the contact hole 211 processed by SAC process is also miniaturized. The size of the contact hole 211 may be also referred to as a hole diameter. The miniaturization of the size of the contact hole 211 makes it difficult to precisely form a hole pattern by lithography techniques.

In order to form the minimized hole pattern precisely, the contact plug may be formed by using a mask pattern having line-shaped (stripe-shaped) openings instead of using a mask pattern having hole openings.

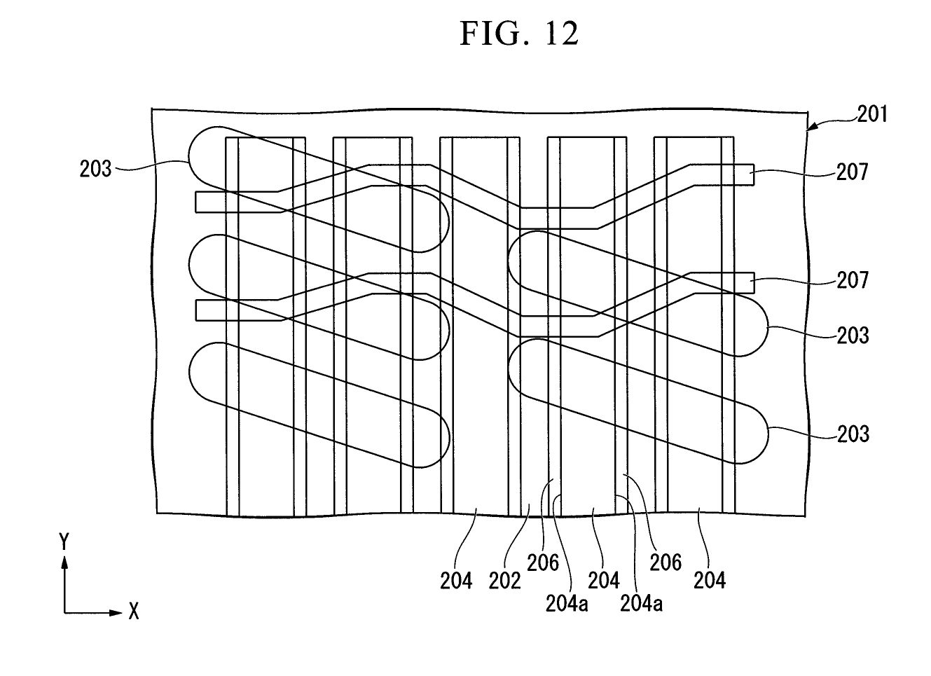

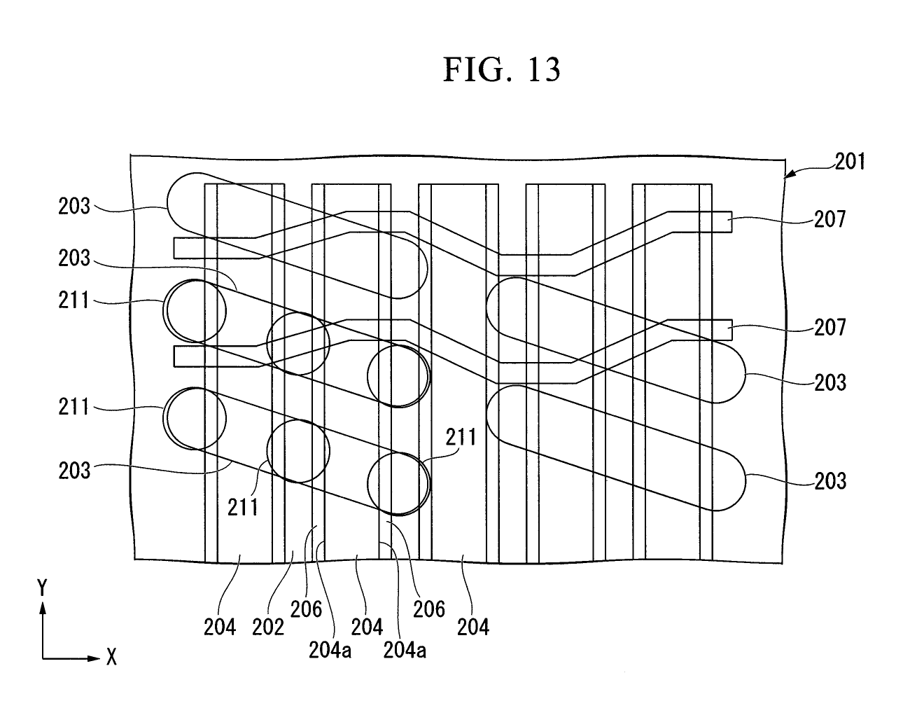

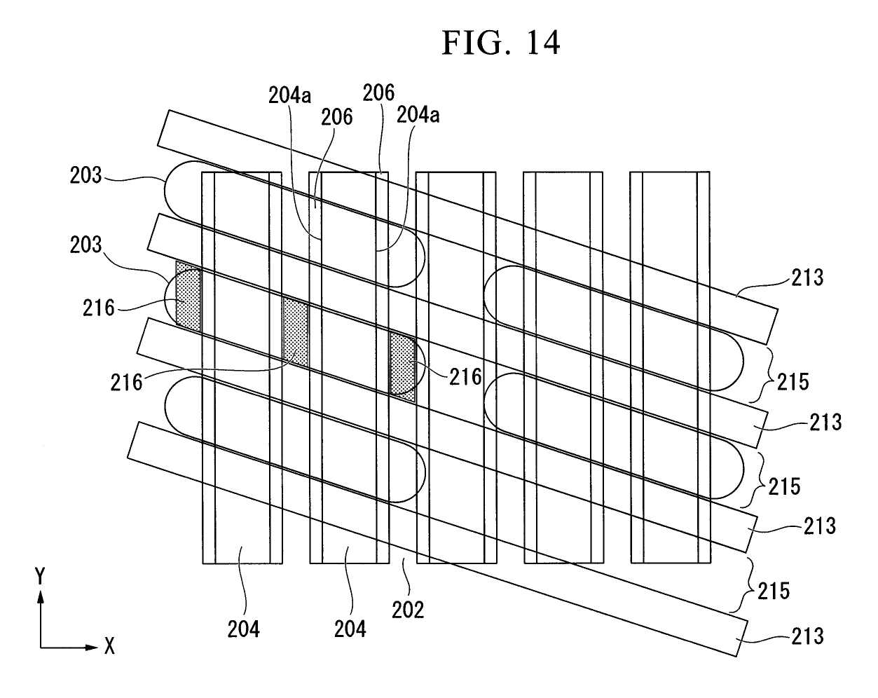

FIG. 14 is a fragmentary plan view illustrating a memory cell including a MOS transistor in accordance with the related art. In FIG. 14, a photoresist pattern 213 for forming a pattern has line-shaped openings. In FIG. 14, the same components as those shown in FIG. 12 are indicated by the same reference numerals. FIG. 14 illustrates three of contact plugs 216. However, three contact plugs 216 are formed over each active region 203 over which the contact plugs 216 are not shown.

As shown in FIG. 14, the photoresist pattern 213 has a line-shape extending along a longitudinal direction of the active region 203. In some cases, the photoresist pattern 213 may be, but is not limited to, a line-and-space pattern. The photoresist pattern 213 has openings 215, each of which extends over the active regions 203. The opening 215 may be a line-shape extending along a longitudinal direction of the active region 203.

The contact plugs 216 are disposed in regions surrounded by the gate electrode 204 (word line) and the photoresist pattern 213.

The contact plugs 216 are formed as follows. The photoresist pattern 213 having the openings 215 is formed over the insulating film (not shown) in which the contact plugs 216 will be formed. The insulating film shown through the opening 215 is selectively removed by an etching process using the photoresist pattern 213 as a mask, thereby forming contact holes in the insulating film. A conductive film which will be processed to form the contact plugs 216 is buried in the contact holes. The conductive film formed on the insulating film and an upper portion of the insulating film are selectively removed by the CMP (Chemical Mechanical Polishing) method. The conductive film remains only in the contact holes, thereby forming the contact plugs 216.

The contact plugs 216 can be formed by the CMP method to polish the conductive film and the insulating film. The CMP method should have to be carried out to precisely control the polishing amount. When the polishing amount is over the intended amount, the gate electrodes 204 are shown and some damage is given to the gate electrodes 204. Also, a short circuit is formed between the gate electrodes 204. The short circuit may be formed by a wiring layer disposed over the insulating film and the contact plugs 216. The wiring layer may connect the gate electrodes 204.

When the polishing amount is under the intended amount, the conductive film for the contact plugs 216 still remains on the insulating film and extends between the contact plugs 216. Adjacent contact plugs 216 are electrically connected with each other through the remaining conductive film, which causes a short circuit between the adjacent contact plugs 216.

When the contact plugs 216 are formed using the CMP method, the thickness of the insulating film, after performing the CMP method or after polishing, should be measured precisely using the spectrometric film thickness measurement system.

The width of the gate electrode 204 is so small that the insulating film on the gate electrode 204 is precisely measured by the spectrometric film thickness measurement system. It is difficult to directly measure, using the spectrometric film thickness measurement system, the thickness of the insulating film formed on the gate electrode 204 after the polishing process.

In the related art, there is no method for precisely measuring the insulating film after performing the CMP method in the case where the contact plugs 216 are formed by the line shape SAC process described above. None of such method results in that it is difficult to precisely estimate the after-polishing-thickness or the polishing amount of the insulating film over the gate electrode 204.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a method of forming a semiconductor device may include, but is not limited to, the following processes. A first film is formed in a device-formation region and a non-device-formation region of a semiconductor substrate. The first film is patterned to form a second film in the device-formation region and a monitoring pattern in the non-device-formation region. First and second structures are formed over the second film and the monitoring pattern respectively. The first structure has substantially the same pattern defined in a horizontal direction as the second structure. The first and second structures are polished.

In some cases, the method may further include, but is not limited to, terminating polishing the first and second structures at the same time or after the monitoring pattern is shown.

In some cases, forming first and second structures may include, but is not limited to, the following processes. A first insulating film is formed over the device-formation region and the non-device-formation region. The first insulating film is selectively removed to form first and second grooves. The first groove is formed in the device-formation region. The second groove is formed in the non-device-formation region. A first conductive film is formed to fill the first and second grooves. The first insulating film and the first conductive film have the first structure in the device-formation region and the second structure in the non-device-formation region.

In some cases, the method may include, but is not limited to, the first groove being substantially the same in width and depth as the second groove.

In some cases, the method may include, but is not limited to, the non-device-formation region is a scribe line region.

In some cases, the method may further include, but is not limited to, measuring a thickness of the monitoring pattern after polishing the first and second structures.

In some cases, the method may further include, but is not limited to, forming a second conductive film in the device-formation region and the non-device-formation region before forming the first film over the second conductive film. Patterning the first film may include, but is not limited to, patterning the first film and the second conductive film to form a third conductive film in the non-device-formation region under the monitoring pattern.

In some cases, the patterning the first film may include, but is not limited to, patterning the first film and the second conductive film to form a gate electrode in the device-formation region.

In some cases, the method may include, but is not limited to, a top surface of the first structure being smaller in area than a top surface of the second structure.

In some cases, the method may include, but is not limited to, the device-formation region being adjacent to a non-device-formation region of the semiconductor substrate.

In another embodiment, a method of forming a semiconductor device may include, but is not limited to, the following processes. First and second structures in a device-formation region and a non-device-formation region respectively are polished concurrently. The first structure has substantially the same pattern defined in a horizontal direction as the second structure. The second structure is over a monitoring pattern. Polishing the first and second structures is terminated at the same time or after the monitoring pattern is shown. A top surface of the first structure is smaller in area than a top surface of the second structure.

In some cases, the method may include, but is not limited to, the non-device-formation region is a scribe line region.

In some cases, the method may further include, but is not limited to, measuring a thickness of the monitoring pattern after polishing the first and second structures.

In still another embodiment, a method of forming a semiconductor device may include, but is not limited to, the following processes. An impurity diffusion layer is formed in a first region of a semiconductor substrate. A first film is formed over the first region and a second region of the semiconductor substrate. The first film is patterned to form a second film and a monitoring pattern in the first and second regions respectively. A third film is formed over the first and second regions. First and second grooves and a contact hole are formed in the third film. The first groove is formed over the second film. The second groove is formed over the monitoring pattern. The impurity diffusion layer is shown through the contact hole. A conductive film is formed to fill the first and second grooves and the contact hole. The conductive film is polished to form a contact plug in the contact hole. The contact plug is in contact with the impurity diffusion layer.

In some cases, the method may further include, but is not limited to, terminating polishing the conductive film at the same time or after the monitoring pattern is shown.

In some cases, the method may further include, but is not limited to, measuring a thickness of the monitoring pattern after polishing the conductive film.

In some cases, the method may include, but is not limited to, the first groove being substantially the same in width and depth as the second groove.

In some cases, the method may include, but is not limited to, a top surface of the second film being smaller in dimension than a top surface of the monitoring pattern.

In some cases, the method may further include, but is not limited to, forming a transistor including the impurity diffusion layer in the first region. The second region is a scribe line.

Hereinafter, a semiconductor device according to an embodiment of the invention will be described in detail with reference to the drawings. In the embodiment, an example of applying the invention to a DRAM (Dynamic Random Access Memory) as the semiconductor device will be described. In the drawings used for the following description, to easily understand characteristics, there is a case where characteristic parts are enlarged and shown for convenience' sake, and ratios of constituent elements may not be the same as in reality. Materials, sizes, and the like exemplified in the following description are just examples. The invention is not limited thereto and may be appropriately modified within a scope which does not deviate from the concept of the invention.

### First Embodiment

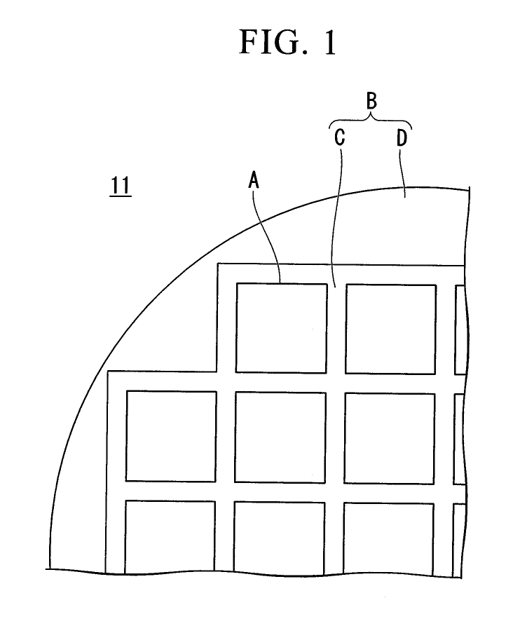

FIG. 1 is a fragmentary plan view illustrating a semiconductor substrate including a plurality of semiconductor devices and a plurality of the insulating film formation regions in accordance with one embodiment of the present invention.

As shown in FIG. 1, a semiconductor substrate 11 may include, but is not limited to, a semiconductor-device-formation region A and a non-semiconductor-device-formation region B. The semiconductor-device-formation region A is a region in which any semiconductor devices are intended to be formed. In some cases, the semiconductor-device-formation region A may include, but is not limited to, a semiconductor device 10. The non-semiconductor-device-formation region B does not include the semiconductor device 10.

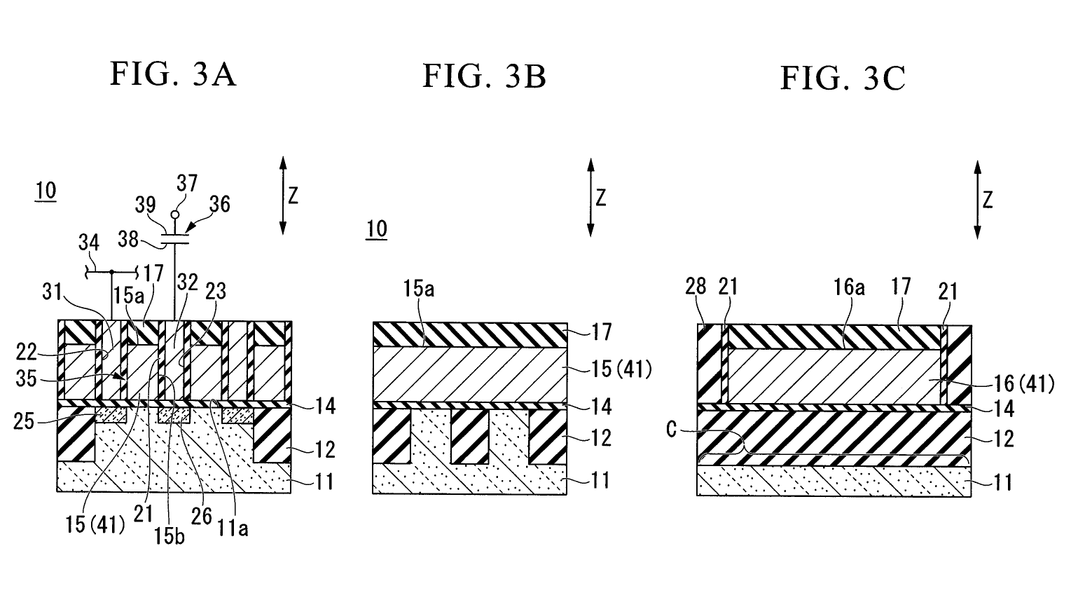

The semiconductor-device-formation region A may include, but is not limited to, a memory cell region (not shown) and a peripheral circuit region (not shown) surrounding the memory cell region. The semiconductor device 10 may include, but is not limited to, a memory cell. The memory cell is formed in the memory cell region. In the memory cell region, a structure which is a part of the semiconductor device 10 is formed as shown in FIGS. 3A and 3B, which will be described below.

The non-semiconductor-device-formation region B is a region in which any semiconductor devices are not intended to be formed.

In some cases, the non-semiconductor-device-formation region B may include a scribe line C and a region D disposed outside the scribe line C. The region D is disposed outside the semiconductor-device-formation regions A isolated by the scribe lines C.

The semiconductor device 10 is formed in each of the semiconductor-device-formation regions A of the semiconductor substrate. The scribe line C is cut to divide the semiconductor substrate 11 into the plurality of the semiconductor devices 10.

The semiconductor substrate 11 may be, but is not limited to, a p-type silicon substrate.

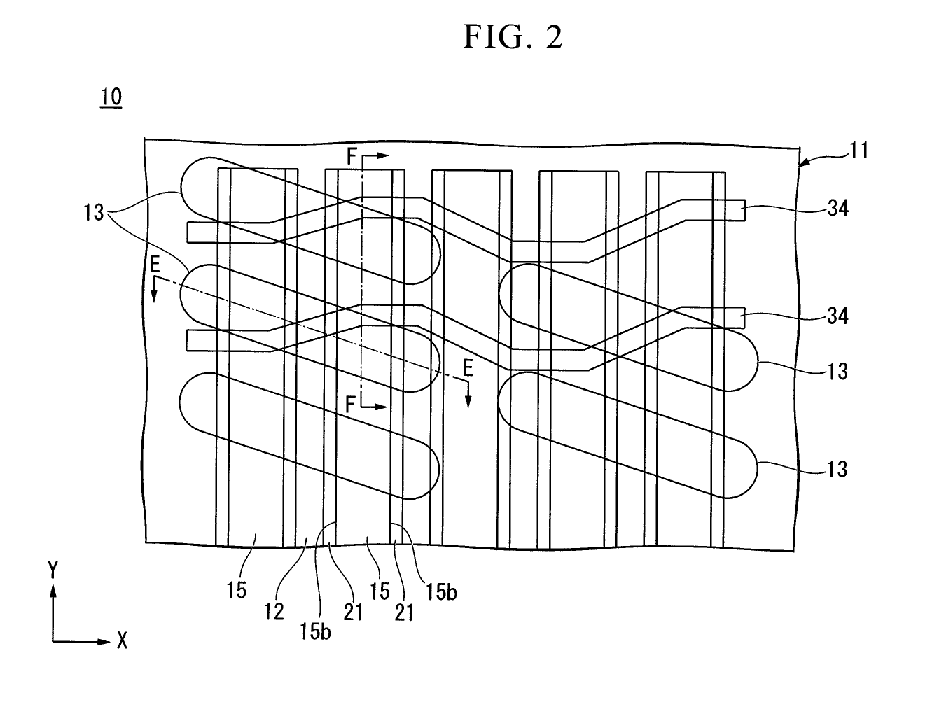

FIG. 2 is a fragmentary plan view illustrating a memory cell provided in the semiconductor device in accordance with the first embodiment of the present invention. FIG. 3A is a fragmentary cross sectional elevation view, taken along an E-E line of FIG. 2, illustrating the semiconductor device 10 shown in FIG. 2 in accordance with the first embodiment of the present invention. FIG. 3B is a fragmentary cross sectional elevation view, taken along an F-F line of FIG. 2, illustrating the semiconductor device 10 in accordance with the first embodiment of the present invention. FIG. 3C is a fragmentary cross sectional elevation view, taken along a scribe line C, illustrating a structure including an insulating film formation region 16 in accordance with the first embodiment of the present invention.

In FIG. 2, Y-direction indicates an extending direction of the gate electrode 15. X-direction crosses Y-direction. In FIG. 3, Z-direction indicates a depth direction of contact holes 22 and 23.

In the present embodiment, a dynamic random access memory (DRAM) will be described as an example of the semiconductor device 10. The plurality of semiconductor devices 10 are formed in semiconductor substrate 11.

As shown in FIGS. 2 and 3A through 3C, the semiconductor substrate 11 may include, but is not limited to, the semiconductor device 10 of the present embodiment and the insulating film formation region 16. As shown in FIG. 3A, the semiconductor device 10 may include, but is not limited to, an isolation region 12, an gate insulating film 14, a gate electrode 15, a cap insulating film 17, side wall films 21, contact holes 22 and 23, impurity diffusion layers 25 and 26, contact plugs 31 and 32, a bit line 34, a capacitor 36, and a plate electrode 37. FIG. 3C illustrates the semiconductor substrate 11, the isolation region 12, the gate insulating film 14, the insulating film formation region 16, the cap insulating film 17, the side wall films 21, and an interlayer insulating film 28, which are formed over the scribe line C of the semiconductor substrate 11. The semiconductor device 10 according to the present embodiment includes a MOS transistor 3 including the gate insulating film 14, the gate electrode 15, and the impurity diffusion layers 25 and 26.

The isolation region 12 is formed of an insulating film buried in a groove (not shown) formed in the semiconductor substrate 11. The isolation region 12 defines an active region 13. The isolation region 12 may be, but is not limited to, a silicon oxide film (SiO₂ film).

The gate insulating film 14 is disposed on a surface of the semiconductor substrate 11 and the isolation region 12. The gate insulating film 14 may be, but is not limited to, a silicon oxide film (SiO₂ film).

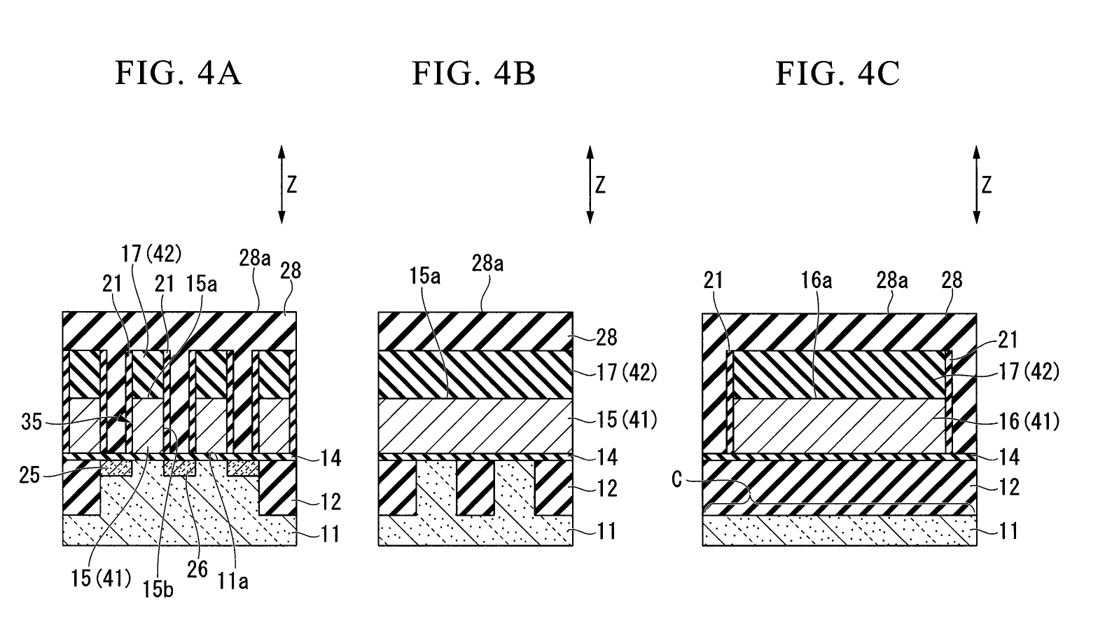

The gate electrode 15 is disposed on the gate insulating film 14 which is formed in the memory cell region of the semiconductor substrate 11. The gate electrode 15 is formed by patterning a first conductive film 41 as shown in FIG. 4 which will be described below. The first conductive film 41 may be, but is not limited to, a poly silicon film containing an n-type impurity or a p-type impurity, a high melting point metal film such as a tungsten film, or a stack thereof.

The insulating film formation region 16 is provided on the gate insulating film 14 on the scribe line C which surrounds the semiconductor-device-formation region A. The insulating film formation region 16 is positioned apart from the gate electrode 15 disposed in the semiconductor-device-formation region A. The insulating film formation region 16 is cut as well as the scribe line C to divide the semiconductor substrate 11 into the plurality of the semiconductor devices 10.

The insulating film formation region 16 is formed by patterning the first conductive film 41 which will be patterned into the gate electrode 15. The insulating film formation region 16 is formed of the same material as the gate electrode 15. The insulating film formation region 16 is substantially the same in thickness as the gate electrode 15.

A cap insulating film 17 is formed on an upper surface 16a of the insulating film formation region 16. The cap insulating film 17 is provided on the gate electrode 15 for monitoring a remaining film thickness of the cap insulating film 17. The “remaining film thickness” represents a thickness of the cap insulating film 17 after the contact plug formation process is carried out. The contact plug formation process will be described in details later.

A size of the upper surface 16a of the insulating film formation region 16 is set so that a thickness of the cap insulating film 17 which is formed on the insulating film formation region 16 can be measured by the spectrometric film thickness measurement system (not shown). The insulating film formation region 16 may be, but is not limited to, a rectangular shape. In some cases, the size may be a dimension in one direction of the upper surface 16a. In other cases, the size may be the area of the upper surface 16a. In this case, the insulating film formation region 16 may be, but is not limited to, more than 60 μm□ in area.

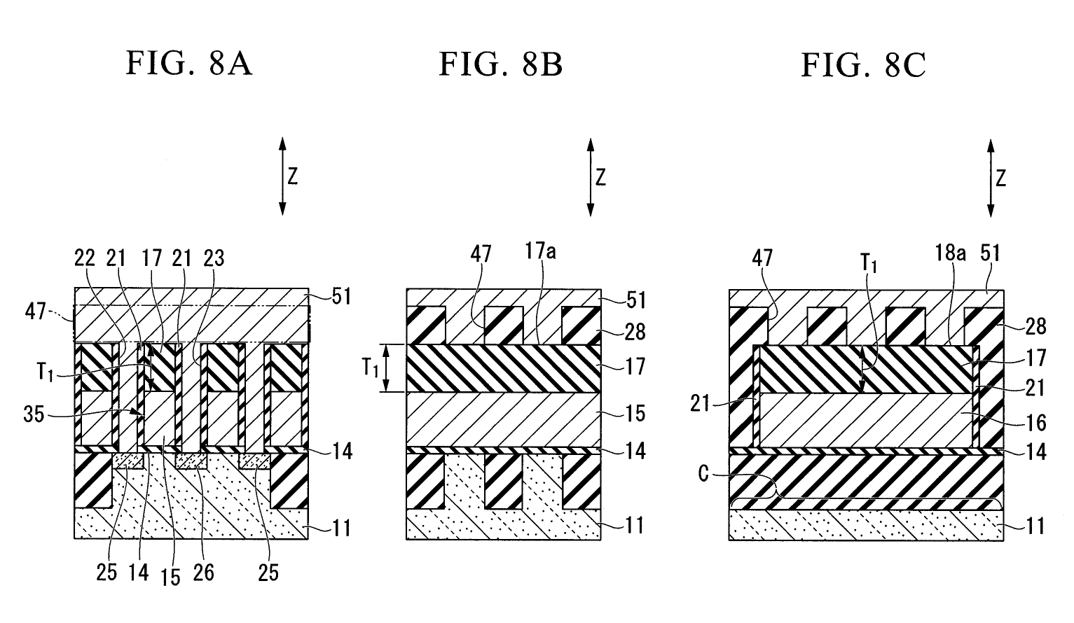

The cap insulating films 17 cover an upper surface 15a of the gate electrode 15 and the upper surface 16a of the insulating film formation region 16. The cap insulating film 17 disposed on the gate electrode 15 suppresses an upper portion of the gate electrode 15 from being etched during an etching process for forming contact holes 22 and 23. The etching process is carried out using SAC (Self Alignment Contact). The cap insulating film 17 disposed on the insulating film formation region 16 functions as a stopper when the contact plugs 31 and 32 are formed by polishing a second conductive film 51, which will be described bellow in FIG. 8C, by CMP (Chemical Mechanical Polishing) method.

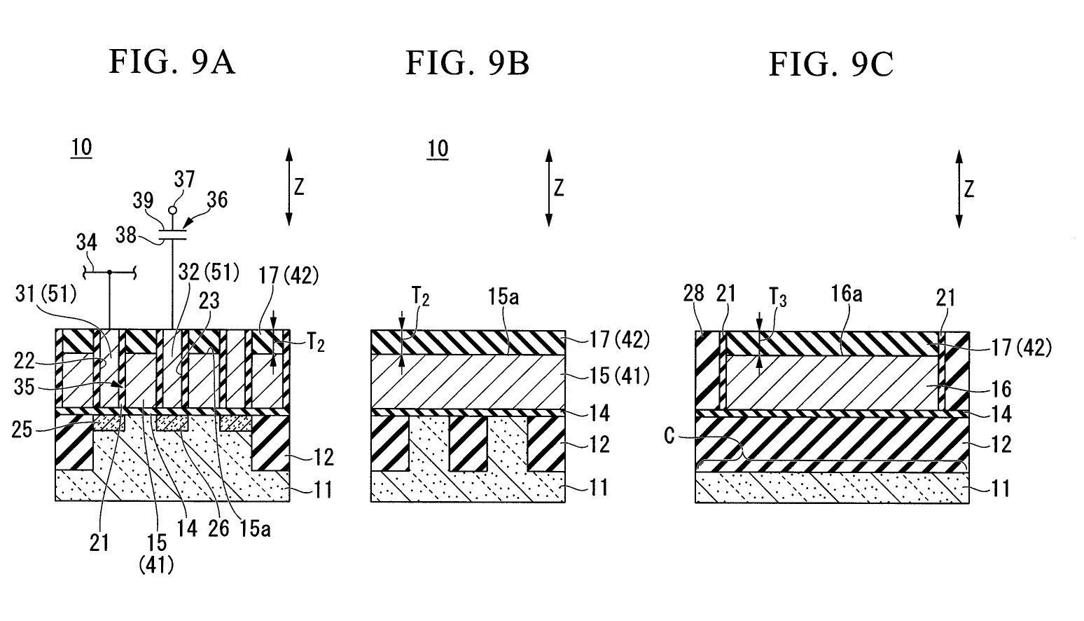

The cap insulating film 17 disposed on the upper surface 16a of the insulating film formation region 16 is used for monitoring the remaining film thickness of the cap insulating film on the gate electrode 15. The “remaining film thickness” represents the thickness of the cap insulating film after the contact plug formation process (after polishing) which will be described below. The remaining film thickness is measured in a process shown in FIGS. 9A through 9C which will be described below.

The cap insulating film 17 formed on the upper surface 16a of the insulating film formation region 16 functions as a remaining film monitoring pattern, as well as the insulating film formation region 16, for monitoring the remaining film thickness of the cap insulating film 17 which is formed over the gate electrode 15.

The cap insulating film 17 is different in etching rate from the interlayer insulating film 28. When the interlayer insulating film 28 is a silicon oxide film (SiO₂ film), the cap insulating film 17 may be, but is not limited to, a silicon nitride film (Si₃N₄ film).

The insulating film formation region 16 and the cap insulating film 17 formed on the insulating film formation region 16 are formed over the scribe line C. When the scribe line is cut to divide the semiconductor substrate 11 into the plurality of the semiconductor devices 10, there are cut the insulating film formation region 16 and the cap insulating film 17 formed over the insulating film formation region 16.

The side wall films 21 cover side surfaces 15b of the gate electrode 15, side surfaces of the insulating film formation region 16, and side surfaces of the cap insulating film 17. The side wall films 21 protect the side surfaces 15b of the gate electrode 15 from being etched when the contact holes 22 and 23 are formed. The side wall films 21 function as a mask when the impurity diffusion layers 25 and 26 are formed in the semiconductor substrate 11.

The side wall films 21 are different in etching rate from the interlayer insulating film 28. When the interlayer insulating film 28 is a silicon oxide film (SiO₂ film), the side wall films 21 may be, but is not limited to, a silicon nitride film (Si₃N₄ film).

The contact holes 22 and 23 are disposed between side wall films 21 provided on the side surfaces 15b of the gate electrode 15. The contact holes 22 and 23 are formed by the SAC. The impurity diffusion layer 25 is shown through the contact hole 22. The impurity diffusion layer 26 is shown through the contact hole 23.

The impurity diffusion layer 25 is disposed in the semiconductor substrate 11 under the contact hole 22. The impurity diffusion layer 25 contacts a bottom of the contact plug 31. The impurity diffusion layer 26 is disposed in the semiconductor substrate 11 under the contact hole 23. The impurity diffusion layer 26 is a common impurity diffusion layer for the gate electrodes 15 adjacent to each other. The impurity diffusion layer 26 contacts a bottom of the contact plug 32. When the semiconductor substrate 11 is the p-type silicon substrate, the impurity diffusion layer 25 and 26 are n-type impurity diffusion layers.

The interlayer insulating film 28 is provided on the gate insulating film 14 on the scribe line C of the semiconductor substrate 11. The interlayer insulating film 28 may be, but is not limited to, a silicon oxide film (SiO₂ film).

The bit line 34 extends in X-direction as shown in FIG. 2. The bit line 34 is disposed over the contact plugs 31 and 32. The bit line 34 extends in not straight. The bit line 34 is electrically connected to the impurity diffusion layer 25 through the contact plug 31.

The capacitor 36 may include, but is not limited to, a lower electrode 38, an upper electrode 39, a capacitor insulating film between the lower electrode 38 and the upper electrode 39. The lower electrode 38 is electrically connected to the impurity diffusion layer 26 through the contact plug 32. A plate electrode 37 is electrically connected to the upper electrode 39.

As shown in FIGS. 3A through 3C, there is flat an upper surface of a structure illustrated in FIGS. 3A through 3C, on which a surface of the cap insulating film 17 is shown. This is because polishing is performed by a CMP apparatus.

FIGS. 4A through 9C illustrates fragmentary cross sectional elevation views involved in a method of forming the semiconductor device in accordance with the present embodiment.

FIGS. 4A, 5A, 7A, 8A, and 9A are fragmentary cross sectional elevation views, taken along the E-E line of FIG. 2, illustrating the semiconductor device in steps involved in the method of forming the semiconductor device of FIG. 3A. FIGS. 4B, 5B, 7B, 8B, and 9B are fragmentary cross sectional elevation views, taken along the F-F line of FIG. 2, illustrating the semiconductor device in steps involved in a method of forming the semiconductor device of FIG. 3B. FIGS. 4C, 5C, 7C, 8C, and 9C are fragmentary cross sectional elevation views, taken along the G-G line of FIG. 2, illustrating the semiconductor device in steps involved in a method of forming the semiconductor device of FIG. 3C.

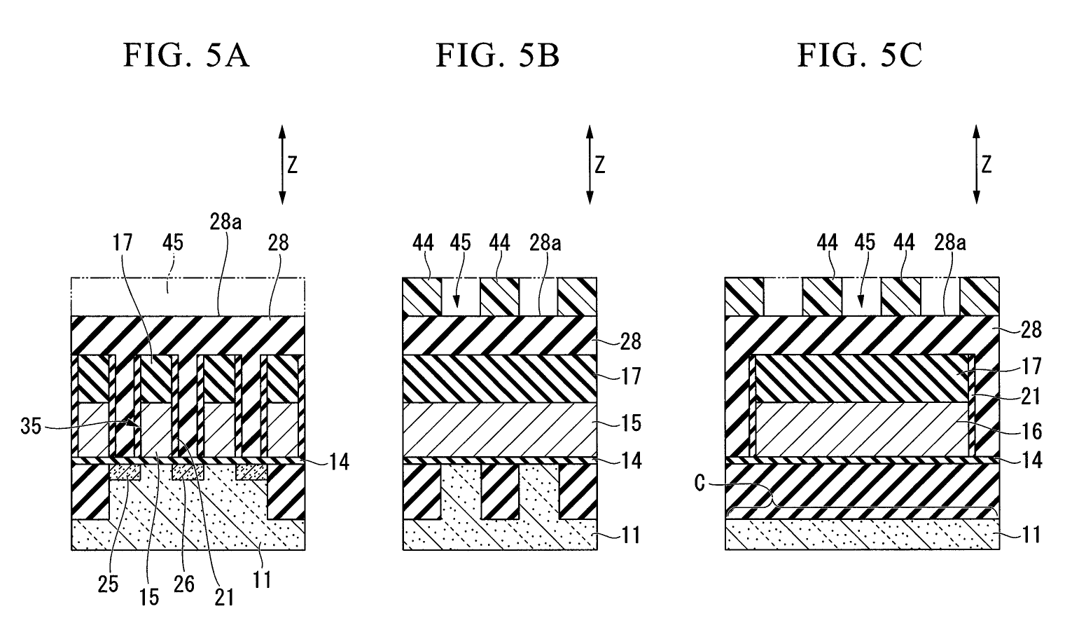

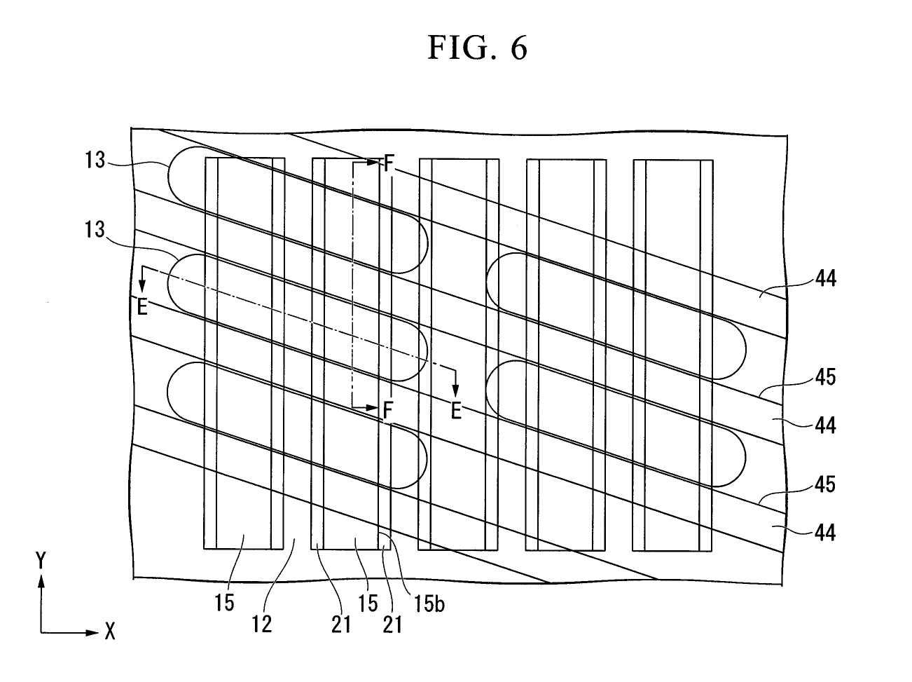

FIG. 6 is a fragmentary plan view illustrating a shape and a position of a photoresist pattern 44 formed in a structure illustrated in FIGS. 5A and 5B. In FIG. 6, the same components as those shown in FIG. 5 are indicated by the same reference numerals. In FIGS. 4A through 9C, the same components as those shown in FIG. 3 are indicated by the same reference numerals.

Hereinafter, the method of manufacturing the semiconductor device 10 will be described with reference to FIGS. 4A through 9C.

As shown in FIGS. 4A through 4C, the p-type silicon substrate is prepared as the semiconductor substrate 11. The groove (not shown) is formed in the semiconductor substrate 11. The isolation region 12 is formed by burying the insulating film, for example, the silicon oxide film (SiO₂ film) by STI (Shallow Trench Isolation method).

The silicon oxide film is formed to cover an upper surface of the isolation region 12 and the surface 11a of the semiconductor substrate 11, thereby forming the gate insulating film 14.

The conductive film 41 and an insulating film 42 are sequentially stacked over the semiconductor substrate 11. The conductive film 41 and the insulating film 42 are patterned, thereby forming the gate electrode 15, the insulating film formation region 16, and the cap insulating film 17. The gate electrode 15 formed of the conductive film 41 is disposed in the semiconductor-device-formation region A. The insulating film formation region 16 formed of the first conductive film 41 is disposed over the scribe line in the non-semiconductor-device-formation region B. The cap insulating film 17 formed of the insulating film 42 covers the upper surface 15a of the gate electrode 15 and the upper surface 16a of the insulating film formation region 16.

The first conductive film 41 may be, but is not limited to, the poly silicon film containing the n-type impurity or the p-type impurity, the high melting point metal film such as the tungsten film, or the stack thereof.

The gate electrode 15 is formed on the gate insulating film 14 disposed in the memory cell region (not shown) in the semiconductor-device-formation region A as shown in FIG. 1. Since the gate electrode 15 has the small width, it is difficult to measure the thickness of a film on the gate electrode by the spectrometric film thickness measurement system.

The insulating film formation region 16 is separate from the gate electrode 15 formed in the semiconductor-device-formation region A. The insulating film formation region 16 is cut as well as the scribe line C when the semiconductor substrate 11 including the semiconductor-device-formation regions A is divided into the plurality of the semiconductor devices 10.

The insulating film formation region 16 is formed by patterning the first conductive film 41 which will be patterned into the gate electrode 15. The insulating film formation region 16 is formed of the same material as the gate electrode 15. The insulating film formation region 16 is substantially the same in thickness as the gate electrode 15.

The cap insulating film 17 is formed on the upper surface 16a of the insulating film formation region 16. The cap insulating film 17 is provided for monitoring the remaining film thickness of the cap insulating film on the gate electrode 15. The “remaining film thickness” represents the thickness of the cap insulating film 17 after the contact plug formation process.

The size of the upper surface 16a of the insulating film formation region 16 is set so that the thickness of the cap insulating film 17 which is formed over the insulating film formation region 16 can be measured by the spectrometric film thickness measurement system (not shown). The insulating film formation region 16 may be, but is not limited to, a rectangular shape. In some cases, the size may be a dimension in one direction of the upper surface 16a. In other cases, the size may be the area of the upper surface 16a. In this case, the insulating film formation region 16 may be, but is not limited to, more than 60 μm□ in area. The insulating film 42 may be, but is not limited to, the silicon nitride film (Si₃N₄ film).

There is formed an insulating film including the same material as the insulating film 42 which is patterned into the cap insulating film 17. The insulating film may be, but is not limited to, the silicon nitride film (Si₃N₄ film). The side wall films 21 are formed to cover the side surfaces 15b of the gate electrode 15, the side surfaces of the insulating film formation region 16, and the side surfaces of the cap insulating film 17 by etching back the insulating film. The side wall films 21 are formed so that the gate insulating film 14 between the side wall films 21 is shown.

The impurity diffusion layers 25 and 26 are formed by implanting the n-type impurity into the surface of the semiconductor substrate 11 by an ion implantation method using the side wall films 21 as a mask.

A MOS transistor 35 is formed, which includes gate insulating film 14, the gate electrode 15, and the impurity diffusion layers 25 and 26.

The interlayer insulating film 28 is formed to cover the cap insulating film 17 and the side wall film 21. The interlayer insulating film 28 is different in etching rate from the cap insulating film 17 and the side wall films 21. When the cap insulating film 17 and the side wall films 21 are the silicon nitride films (Si₃N₄ films), the interlayer insulating film 28 may be, but is not limited to, the silicon oxide film (SiO₂ film) or BPSG (boro-phospho silicate glass).

An upper surface 28a of the interlayer insulating film 28 is polished to be planarized by the CMP method.

The planarization of the upper surface 28a of the interlayer insulating film 28 permits a fine exposure process to form the photoresist pattern 44 as shown in FIGS. 5A through 5C and 6. The accuracy in dimension of the openings 45 can be improved. The photoresist pattern 44 is formed on the interlayer insulating film 28. The photoresist pattern 44 has groove-shaped openings 45 as shown in FIGS. 5A through 5C and 6.

As shown in FIGS. 5A through 5C and 6, the photoresist pattern 44 is formed entirely on the upper surface 28a of the interlayer insulating film 28. In other words, the photoresist pattern 44 is formed on the upper surface 28a of the interlayer insulating film 28 in the semiconductor-device-formation region A and the non-semiconductor-device-formation region B. The photoresist pattern 44 extends in a longitudinal direction of the active region 13. The photoresist pattern 44 has the line-shaped. The photoresist pattern 44 has groove-shaped openings 55. The groove-shaped openings 45 are formed over the active region 13. The groove-shaped openings 45 extend along the longitudinal direction of the active region 13.

The photoresist pattern 44 having the groove-shaped openings 45 is formed on the upper surface 28a of the interlayer insulating film 28 formed on the cap insulating film 17.

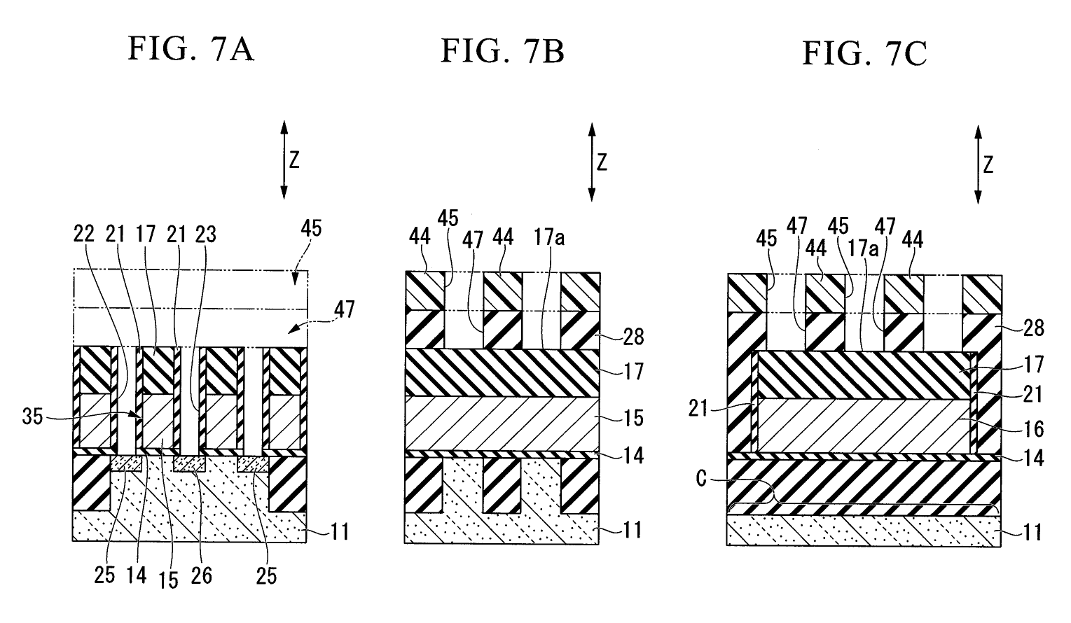

As shown in FIGS. 7A through 7C, the interlayer insulating film 28 which is positioned under the groove-shaped openings 45 is selectively removed by an anisotropic etching process using the photoresist pattern 44 as a mask. Thus, a plurality of grooves 47 is formed in the interlayer insulating film 28 which is formed over the cap insulating film 17 while the contact holes 22 and 23 are formed in the insulating film 28 which is positioned under the groove 47 in the memory cell region. An upper surface of the impurity diffusion layer 25 is shown through the contact hole 22. An upper surface of the impurity diffusion layer 26 is shown through the contact hole 23.

Thus, the plurality of grooves 47 are formed on the cap insulating film 17. The plurality of grooves 47 are the same in width and depth as each other. An upper surface 17a of the cap insulating film 17 is shown through the plurality of grooves 47.

The above described anisotropic etching process is performed under conditions that the silicon nitride films of the cap insulating film 17 and the side wall films 21 are hard to be etched. The cap insulating film 17 and the side wall films 21 functions as an etching stopper film. In other words, the contact holes 22 and 23 are formed by the SAC (Self Alignment Contact) method.

As shown FIGS. 8A through 8C, the photoresist pattern 44 illustrated in FIGS. 7A through 7C is removed. The second conductive film 51 is buried in the contact holes 22 and 23 and the plurality of grooves 47.

Structures shown in FIGS. 8A through 8C are formed on the cap insulating film 17 disposed on the gate electrode 15 and on the cap insulating film 17 disposed on the insulating film formation region 16. The structures include the interlayer insulating film 28 having the plurality of grooves 47 and the second conductive film 51 buried in the plurality of grooves. The structures have substantially the same pattern defined in a horizontal direction. The structure over the gate electrode 15 is smaller in width than the structure over the insulating film formation region 16. The structure over the gate electrode 15 may be smaller in area than the structure over the insulating film formation region 16.

The second conductive film 51 may be formed by, but is not limited to, the CVD (Chemical Vapor Deposition). The second conductive film 51 may be, but is not limited to, a poly silicon film containing a p-type or an n-type impurity, a sequential stack of a barrier film such as a titanium nitride (TiN) film and a tungsten (W) film.

As shown in FIGS. 9A through 9C, upper surfaces of the structures illustrated in FIGS. 8A through 8C are concurrently polished by the CMP method until the cap insulating film 17 on the gate electrode 15 and the cap insulating film 17 on the insulating film formation region 16 are shown. Polishing the upper surfaces of the structures are terminated at the same time or after the cap insulating film 17 on the gate electrode 15 and the cap insulating film 17 on the insulating film formation region 16 are shown. Thus, the contact plugs 31 and 32 are formed in the contact holes 22 and 23, respectively.

As described above, before the polishing step, the structures were formed on the cap insulating film 17 disposed on the gate electrode 15 and on the cap insulating film 17 disposed on the insulating film formation region 16. The structures include the interlayer insulating film 28 having the plurality of grooves 47 and the second conductive film 51 buried in the plurality of grooves.

Therefore, the structure on the insulating film formation region 16, illustrated in FIG. 8C, is etched at the same rate as the first structure on the gate electrode 15. The upper surface 17a of the cap insulating film 17 on the gate electrode 15 and the upper surface 17a of the cap insulating film 17 on the insulating film formation region 16 are shown at the same timing.

A thickness T₂ of the cap insulating film 17 which is formed on the gate electrode 15 is substantially the same as a thickness T₃ of the cap insulating film 17 which is formed on the insulating film formation region 16. The thickness T₂ of the cap insulating film 17 which is formed on the gate electrode 15 is difficult to be measured by the spectrometric film thickness measurement system since the width of the gate electrode 15 is small. The thickness T₃ of the cap insulating film 17 which is formed on the insulating film formation region 16 is possible to be measured by the spectrometric film thickness measurement system.

The cap insulating film 17 formed on the upper surface 16a of the interlayer insulating film 16 can be used for monitoring the remaining film thickness of the cap insulating film 17 disposed on the gate electrode 15. The “remaining film thickness” represents the thickness of the cap insulating film 17 after the contact plug formation process.

The thickness T₂ (=T₃) of the cap insulating film 17 disposed on the gate electrode 15 can be precisely estimated by measuring the thickness T₃ of the cap insulating film 17 disposed on the insulating film formation region 16 after the contact plug formation process (after polishing).

In general, the second conductive film 51 is over-polished in consideration of the variation of polishing rate depending on positions of the semiconductor substrate 11.

Thus, the cap insulating film 17 is slightly polished. The thickness T₂ and the thickness T₃ after polishing are smaller than the thickness T₁ of the cap insulating film 17 before polishing.

After forming the contact plugs 31 and 32 (that is, polishing), the thickness T₃ of the cap insulating film 17 shown in FIG. 9C is measured by the spectrometric film thickness measurement system. The cap insulating film 17 shown in FIG. 9C is disposed on the upper surface 16a of the insulating film formation region 16.

As described above, the thickness T₃ of the cap insulating film 17 is substantially the same as the thickness T₂ of the cap insulating film 17. Therefore, the thickness T₂ can be precisely estimated without measuring the thickness T₂. Also, the thickness T₂ of the cap insulating film 17 after polishing (polishing amount) can be easily controlled.

The spectrometric film thickness measurement system may be, but is not limited to, the spectroscopic ellipsometers and the reflective spectrometric film thickness measurement system which are commercially available.

When the thickness T₃ of the cap insulating film 17 is greater than the predetermined thickness, an additional polishing process is performed. Then, the thickness T₃ of the cap insulating film 17 is measured again. Thus, the productivity of the semiconductor device 10 can be improved.

Other interlayer insulating film (not shown), a plug, a wiring, the bit line 34, and the capacitor 36 and the like are formed by the known method.

The structure shown in FIGS. 9A through 9C is cut on the scribe line. The plurality of the semiconductor devices 10 formed in the semiconductor substrate 11 are divided into each element of the semiconductor devices 10, thereby forming the plurality of semiconductor devices.

According to the method of forming the semiconductor device of the present embodiment, the structures shown in FIGS. 8A through 8C are formed on the cap insulating film 17 disposed on the gate electrode 15 and on the cap insulating film 17 disposed on the insulating film formation region 16. The structure includes the interlayer insulating film 28 having the plurality of grooves 47 and the second conductive film 51 buried in the plurality of the grooves 47.

The structure formed on the insulating film formation region 16, shown in FIG. 8C, is polished at the same rate as the structure formed on the gate electrode 15. The upper surface 17a of the cap insulating film 17 on the gate electrode 15 and the upper surface 17a of the cap insulating film 17 on the insulating film formation region 16 are shown at the same timing.

The thickness T₂ of the cap insulating film 17 disposed on the gate electrode 15 (remaining film thickness) is substantially the same as the thickness T₃ of the cap insulating film 17 disposed on the insulating film formation region 16. The thickness T₂ of the cap insulating film 17 is difficult to be measured by the spectrometric film thickness measurement system. The thickness T₃ of the cap insulating film 17 is possible to be measured by the spectrometric film thickness measurement system.

The cap insulating film 17 provided on the upper surface 16a of the insulating film formation region 16 can be used for monitoring the remaining film thickness of the cap insulating film 17 disposed on the gate electrode 15. The “remaining film thickness” represents the thickness of the cap insulating film 17 after the contact plug formation process.

The thickness T₂ (=T₃) of the cap insulating film 17 disposed on the gate electrode 15 can be precisely estimated by measuring the thickness T₃ of the cap insulating film 17 disposed on the insulating film formation region 16 after the contact plug formation process (polishing).

### Comparative Example

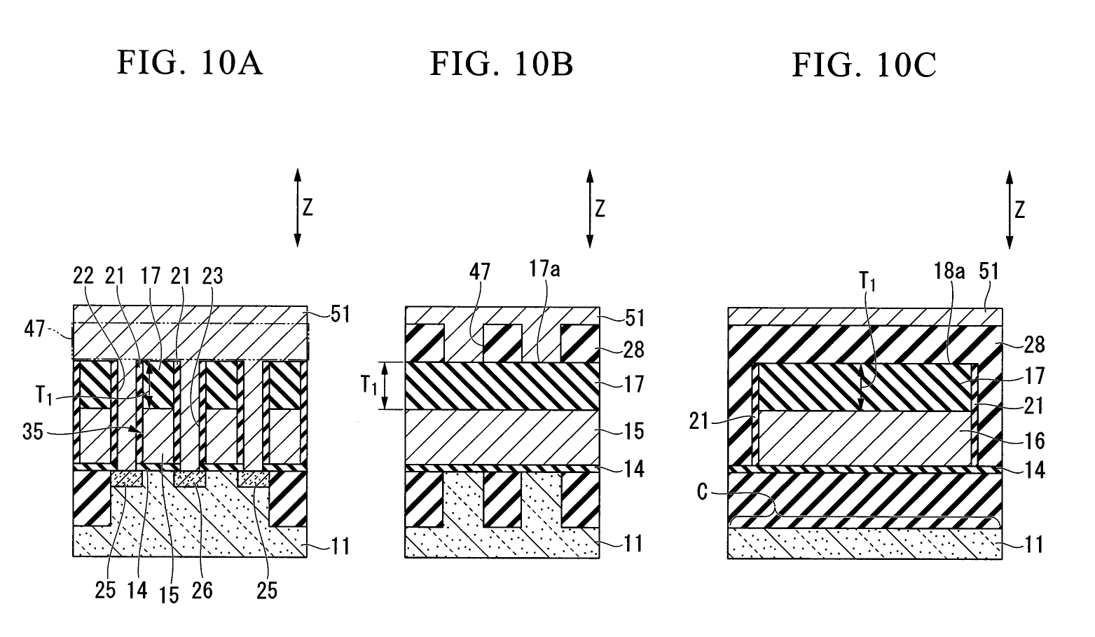

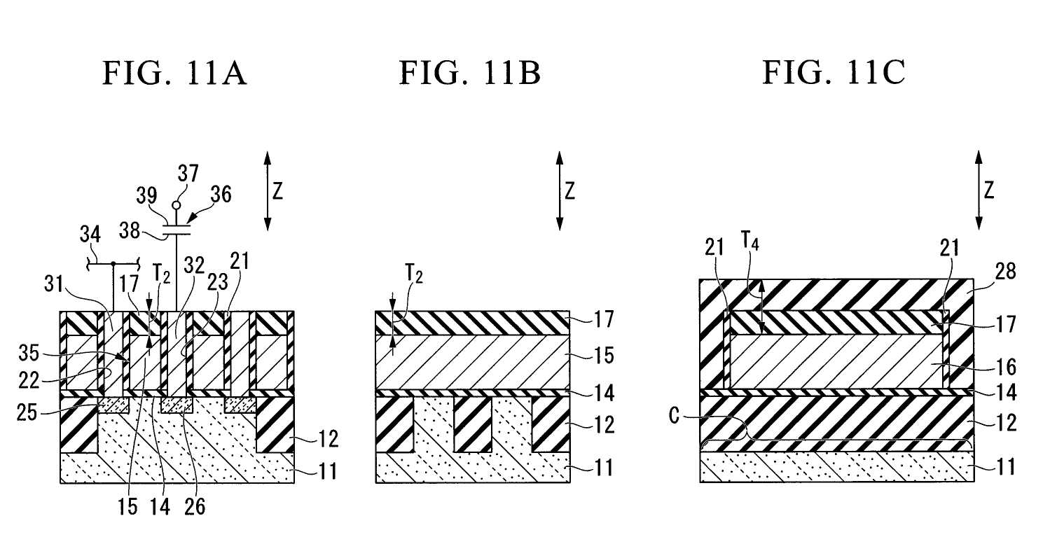

FIGS. 10A through 11C are fragmentary cross sectional elevation views illustrating a semiconductor device involved in steps of a method of forming a semiconductor device according to a comparative example. FIGS. 10A through 10C illustrate the semiconductor device in a step equivalent of the step of FIGS. 8A through 8C. FIGS. 11A through 11C illustrates the semiconductor device in a step equivalent of the step of FIGS. 9A through 9C. In FIGS. 10A through 10C, the same components as those shown in FIGS. 8A through 8C are indicated by the same reference numerals. In FIGS. 11A through 11C, the same components as those shown in FIGS. 9A through 9C are indicated by the same reference numerals.

As shown in FIG. 10B, before the polishing process, the interlayer insulating film 28 having a plurality of grooves 47 and the second conductive film 51 buried in the plurality of the groove 47 are formed over the cap insulating film 17. On the other hand, as shown in FIG. 10C, the interlayer insulating film 28 without the groove 47 and the second conductive film 51 stacked on the interlayer insulating film 28.

In the comparative example, the structure, shown in FIG. 10B, formed on the cap insulating film 17 which is formed on the gate electrode 15 is different from the structure, shown in FIG. 10C, formed on the cap insulating film 17 which is formed on the insulating film formation region 16.

When the second conductive film 51 is polished, there is used polishing agent by which the second conductive film 51 is easily polished and an insulating film such as a silicon oxide film and a silicon nitride film is hardly polished.

As shown in FIGS. 11A through 11C, when the second conductive film 51 is polished by the CMP method, the structure, shown in FIG. 10B, formed on the cap insulating film 17 is polished faster than the structure, shown in FIG. 10C, formed on the cap insulating film 17. The cap insulating film 17 shown in FIG. 11B is shown earlier than the cap insulating film 17 shown in FIG. 11C.

After polishing (forming the contact plugs 31 and 32), a thickness T₄ of an insulating film on the insulating film formation region 16 is substantially different from the thickness T₂ of the cap insulating film 17 shown in FIG. 11B. The insulating film on the insulating film formation region 16 includes the cap insulating film 17 and the polished interlayer insulating film 28 shown in FIG. 11C.

The insulating film formation region 16 and the cap insulating film 17 formed on the insulating film formation region 16 may not be used as a monitor pattern of the remaining film thickness of the cap insulating film 17 formed on the gate electrode 15.

In the case of the structure in the comparative example, the thickness of the cap insulating film 17 after polishing cannot be precisely estimated when the thickness T₄ of the insulating film on the insulating film formation region 16 is measured.

In some cases, the insulating film formation region 16 is formed over the scribe line C, but is not limited to. In other cases, the insulating film formation region 16 may be formed in region D shown in FIG. 1. In this case, the insulating film formation region 16 may be formed adjacent to scribe line C and apart from an outer circumference of the semiconductor substrate 11, which makes a difference between the thickness T₂ of the cap insulating film 17 and the thickness T₃ of the cap insulating film 17 small.

The semiconductor device 10 according to the present embodiment includes the planer type transistor as the MOS transistor 35, but is not limited to. The present embodiment is also applicable to a semiconductor device including a transistor including the following elements. The gate electrode is buried in a groove of the semiconductor substrate 11. The gate insulating film is interposed between the gate electrode and a surface of the groove. The gate electrode protrudes from the surface 11a of the semiconductor substrate 11.

The present embodiment is applicable to methods of forming any other semiconductor devices.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

Furthermore, the particular features, structures, or characteristics may be combined in any suitable manner in one or more embodiments.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A method of forming a semiconductor device, the method comprising:
forming a first film in a device-formation region and a non-device-formation region of a semiconductor substrate;
patterning the first film to form a second film in the device-formation region and a monitoring pattern in the non-device-formation region;
forming first and second structures over the second film and the monitoring pattern respectively, the first structure having substantially the same pattern defined in a horizontal direction as the second structure; and
polishing the first and second structures.

2. The method according to claim 1 further comprising:
terminating polishing the first and second structures at the same time or after the monitoring pattern is shown.

3. The method according to claim 1, wherein forming first and second structures comprises:
forming a first insulating film over the device-formation region and the non-device-formation region;
selectively removing the first insulating film to form first and second grooves, the first groove being formed in the device-formation region, the second groove being formed in the non-device-formation region; and
forming a first conductive film to fill the first and second grooves,
wherein the first insulating film and the first conductive film have the first structure in the device-formation region and the second structure in the non-device-formation region.

4. The method according to claim 1, wherein the first groove is substantially the same in width and depth as the second groove.

5. The method according to claim 1, wherein the non-device-formation region is a scribe line region.

6. The method according to claim 1, further comprising:
measuring a thickness of the monitoring pattern after polishing the first and second structures.

7. The method according to claim 1, further comprising:
forming a second conductive film in the device-formation region and the non-device-formation region before forming the first film over the second conductive film,
wherein patterning the first film comprises:
patterning the first film and the second conductive film to form a third conductive film in the non-device-formation region under the monitoring pattern.

8. The method according to claim 7, wherein patterning the first film comprises:
patterning the first film and the second conductive film to form a gate electrode in the device-formation region.

9. The method according to claim 1, wherein a top surface of the first structure is smaller in area than a top surface of the second structure.

10. The method according to claim 1, wherein the device-formation region is adjacent to a non-device-formation region of the semiconductor substrate.

11. The method according to claim 1, wherein a dimension in one direction of the top surface of the second structure is more than 60 μm.

12. A method of forming a semiconductor device, the method comprising:
polishing first and second structures concurrently in a device-formation region and a non-device-formation region respectively, the first structure having substantially the same pattern defined in a horizontal direction as the second structure, the second structure being over a monitoring pattern; and
terminating polishing the first and second structures at the same time or after the monitoring pattern is shown,
wherein a top surface of the first structure is smaller in area than a top surface of the second structure.

13. The method according to claim 12, wherein the non-device-formation region is a scribe line region.

14. The method according to claim 12, further comprising:
measuring a thickness of the monitoring pattern after polishing the first and second structures.

15. A method of forming a semiconductor device, the method comprising:
forming an impurity diffusion layer in a first region of a semiconductor substrate;
forming a first film over the first region and a second region of the semiconductor substrate;
patterning the first film to form a second film and a monitoring pattern in the first and second regions respectively;
forming a third film over the first and second regions;
forming first and second grooves and a contact hole in the third film, the first groove being formed over the second film, the second groove being formed over the monitoring pattern, the impurity diffusion layer being shown through the contact hole;
forming a conductive film to fill the first and second grooves and the contact hole; and
polishing the conductive film to form a contact plug in the contact hole, the contact plug being in contact with the impurity diffusion layer.

16. The method according to claim 15 further comprising:
terminating polishing the conductive film at the same time or after the monitoring pattern is shown.

17. The method according to claim 16, further comprising:
measuring a thickness of the monitoring pattern after polishing the conductive film.

18. The method according to claim 15, wherein the first groove is substantially the same in width and depth as the second groove.

19. The method according to claim 15, wherein a top surface of the second film is smaller in dimension than a top surface of the monitoring pattern.

20. The method according to claim 15, further comprising:
forming a transistor including the impurity diffusion layer in the first region,
wherein the second region is a scribe line.
